(19) United States
(12) Patent Application Publication
(10) Pub. No.: US 2007/0083479 A1
(43) Pub. Date: Apr. 12, 2007

(54) METHOD, APPARATUS AND PROGRAM STORAGE DEVICE FOR PROVIDING A PREPAID METERING SYSTEM

(76) Inventors: Stephen Brant Swartz, Chattanooga, TN (US); Eoin Patrick Heaney, Nokomis, FL (US); Frederick Hamilton Ward III, Poway, CA (US)

Correspondence Address: David W. Lynch;Chambliss, Bahner & Stophel, 1000 Tallan Building, Two Union Square, Chattanooga, TN, 37402, US

(21) Appl. No.: 11/531,979

(22) Filed: Sep. 14, 2006

Related U.S. Application Data
(60) Provisional application No. 60/717,069, filed on Sep. 14, 2005.

(51) Int. Cl. G01R 21/133

(52) U.S. Cl. 705/412

(57) ABSTRACT

A method, apparatus and program storage device for providing a prepaid metering system an electric utility meter interface. The prepaid metering system includes a meter interface a customer interface unit and a revenue management system.

### BACKGROUND OF THE INVENTION

1. Field of the Invention.

This invention relates in general to a prepaid metering of utilities, and more particularly to a method, apparatus and program storage device for providing a prepaid metering system.

2. Description of Related Art.

Conventionally, the supply of electricity to a user station, such as a domestic house, is measured by a rotary disc or simple electronic meter which is periodically and visually read by a human meter reader, to prepare accounts for payment by the user, for use during a period in the past. Prepaid systems are also known where no human meter reader is required, but where the user pays in advance for a quantum of electricity to be used in future. More recently, prepayment metering systems have been proposed for overcoming some of the shortcomings of the traditional billing system. These prepayment systems were designed so that the purchase of a supply of electricity, gas, or water is made at a central station such as the gas or electric utility office. The information regarding the amount of the purchase is then communicated to the customer site where the utilities are consumed.

According to the industry reports, the U.S. has only 100,000 prepayment meters deployed. The 100,000 prepayment meters in the U.S. are only a small fraction of the 6-million prepayment meters deployed worldwide. There are many reasons that more prepayment systems have not been installed. For example, there has been a lack of integration with other enterprise level systems. Further, there was a need for proprietary meters from a single vendor and there was a lack of adequate post-sale support by existing vendors. In addition, the per-meter cost has been too high in the past. From a consumer standpoint, prepayment systems have offered the consumer limited vending options.

Despite these shortcomings, the prepayment industry can expand dramatically over the next several years as utilities grapple with bad consumer debt and seek out cost saving technologies.

It can be seen then that there is a need for a method, system and program storage device that provides a unique and technically advanced prepayment solution that will be readily accepted by these utilities.

### SUMMARY OF THE INVENTION

To overcome the limitations in the prior art described above, and to overcome other limitations that will become apparent upon reading and understanding the present specification, the present invention discloses a method, apparatus and program storage device for providing a prepaid metering system.

The present invention solves the above-described problems by providing a prepayment meter system that integrates with other enterprise level systems including Automatic Meter Reading (AMR) systems. The prepayment meter system adapts to industry standard meters for use in the system. Maintenance and monitoring tools are provided that ensures reliable system operation. A wide range of consumer vending options is also provided. The prepayment meter system provides the consumer with timely accurate information regarding their consumption and provides a cost effective solution for the utility companies. Further prepayment benefits to the utility include elimination of bad debt, improved cash flow, cost reduction and increased customer satisfaction. Further consumer benefits include self-management of energy costs and reduced costs associated with security deposits and disconnecting and reconnecting electrical services.

An electric utility meter interface according to one embodiment of the present invention includes a switch for controlling a connection of electric service to a customer and a controller, coupled to the switch, for processing data regarding electricity usage by the customer, maintaining electricity usage credits for the customer and controlling the switch based on the usage credits of the customer and the data regarding electricity usage by the customer.

In another embodiment of the present invention, a customer interface unit is provided. The customer interface unit includes a display for communicating information to an electric customer and a user interface for entering electricity usage credits for the customer and obtaining information about usage and available credits.

In another embodiment of the present invention, a revenue management system is provided. The revenue management system includes a controller for controlling dispensation of utility service credits and an interface, coupled to the controller, for accepting payment for utility service credits from a customer and for issuing utility service credits to the customer upon payment by the customer.

In another embodiment of the present invention, a method for providing prepaid utility metering is provided. The method includes paying by a consumer for a utility credit via a vending device, providing a transfer number to the consumer in response to receipt of the payment, entering the transfer number using the CIU, transferring the utility credit to the prepaid meter and adding to any remaining utility balance already in the meter, storing utility credit in the meter and decrementing the utility credit as used and disconnecting the meter from the utility power supply when available credit in the meter reaches zero while maintaining power to the CIU.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 illustrates a revenue management system (RMS) architecture according to an embodiment of the present invention;

FIG. 2 illustrates a point of sale (POS) network according to an embodiment of the present invention;

FIG. 3 illustrates a prepayment module (PPM) that is installed inside a meter according to an embodiment of the present invention;

FIG. 4 illustrates a consumer interface unit (CUI) according to an embodiment of the present invention;

FIG. 5 is a screen shot showing the functioning of the revenue management system (RMS) according to an embodiment of the present invention;

FIG. 6 is a screen shot showing the vending function of the revenue management system (RMS) according to an embodiment of the present invention;

FIG. 7 illustrates the data storage device providing the instructions for perform the steps necessary to implement and/or use the present invention;

FIG. 8 is a table that lists some of the advantages of a system according to embodiments of the present invention;

FIG. 9 is a table showing further benefits of the system when used in conjunction with an AMR system or system having analogous capabilities according to an embodiment of the present invention; and

FIG. 10 is a flow chart of the method for providing prepaid metering according to one embodiment of the present invention.

### DETAILED DESCRIPTION OF THE INVENTION

In the following description of the embodiments, reference is made to the accompanying drawings that form a part hereof, and in which is shown by way of illustration the specific embodiments in which the invention may be practiced. It is to be understood that other embodiments may be utilized because structural changes may be made without departing from the scope of the present invention.

The present invention provides a method, apparatus and program storage device for providing a prepaid metering system. The system according to an embodiment of the present invention provides a prepayment meter system that integrates with other enterprise level systems including Automatic Meter Reading (AMR) systems, billing systems, CIS systems and accounting/financial systems. The prepayment meter system adapts to industry standard meters for use in the system. Maintenance and monitoring tools are provided that ensures reliable system operation. A wide range of consumer vending options is also provided. The prepayment meter system provides the consumer with timely accurate information regarding their consumption and provides a cost effective solution for the utility companies. Further prepayment benefits to the utility include elimination of bad debt, improved cash flow, cost reduction and increased customer satisfaction. Further consumer benefits include self-management of energy costs and reduced costs associated with security deposits and disconnecting and reconnecting electrical services.

The prepayment system according to an embodiment of the present invention includes four system level components that are integrated with the utility infrastructure.

The prepayment system manages all aspects of the prepayment transaction and service delivery. Each time the consumer buys electricity, the dollar-amount they choose to spend is converted to utility service credits. By way of example, in the electric utility industry, service credits may be represented as a number kilowatt hours, as a dollar amount or by some other type of meaningful unit which may be specified by the utility. These credits are encrypted in a numeric code: the transfer number. The consumer enters this transfer number using the keypad on the Consumer Interface Unit, which in turn transmits it to the PPM in their meter via a wireless RF link. The PPM decodes the transfer number, stores the received service credits in memory and then decrements the stored credit as service is used. When credit is exhausted, the PPM is capable of automatically disconnecting service in meters equipped with a disconnect switch (also referred to as a disconnect relay). When credit is again added, the PPM signals the disconnect switch to reconnect, restoring service to the premises. Safeguards are built into the prepayment system to prevent disconnection when it might unduly inconvenience or endanger the consumer.

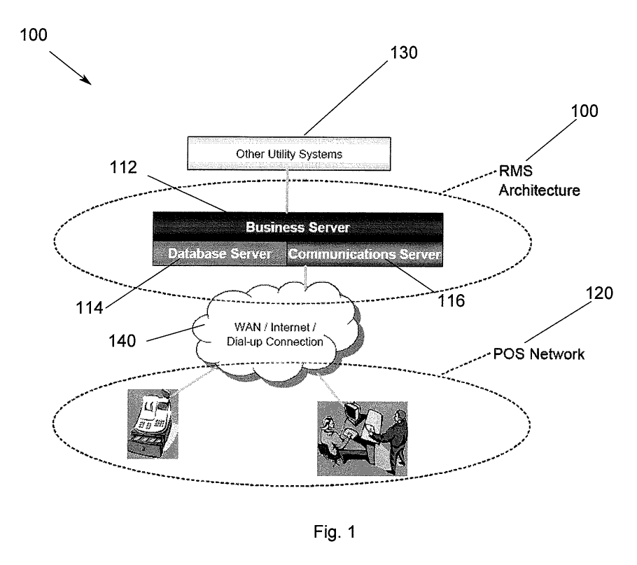

FIG. 1 illustrates a revenue management system (RMS) 100 according to an embodiment of the present invention. The RMS 100 provides a back-office function that enables the sale of prepaid electricity and tracks the resulting revenues. The information technology (IT) infrastructure of a utility company typically includes at minimum an existing billing/customer service computer system and a financial/accounting computer system. A revenue management system (RMS) architecture 110 is provided to control all aspects of prepaid electricity sales at a point of sale (POS) network 120 and provides the interface to other utility systems 130. The RMS architecture 110 also authorizes all sales transactions.

The RMS 100 provides a single interface for managing all activities related to prepayment. The RMS 100 is installed on dedicated servers connected to the utility's existing IT infrastructure. The RMS 100 is a scalable client/server based software application. A broadbased database system, such as a SQL database, ensures broad compatibility with other utility applications and allows for rapid customization. Each installation can be configured and customized based on the utility's particular requirements. Specific interfaces to other utility systems can also be supported in the RMS for enhanced integration.

Functionally, the RMS architecture 110 includes of a business server 112, a database server 114 and communications server 116. The business server 112 implements the business logic layer of the system. Access to the system is controlled by assigning individual user profiles and restricting what functions each user has access to. Overall system configuration is accomplished through the business server 112.

The database server 114 contains the RMS database and provides secure access to it via an industry-standard software interface. For example, a Windows 2000 operating system and Database Management System (DBMS) such as MS SQL Server may be used. A record for each prepayment consumer is created in the RMS database. These records can be imported from the utility's master customer files.

The communications server 116 provides a secure portal between the RMS business server 112 and a POS Network 120 (as described in greater detail below). The communications server 116 includes server software, such as Microsoft's IIS Web Server and ASP server, as well as proprietary software for handling Internet and dial-up communications with the POS Network 120.

The business 112, database 114 and communications 116 servers may all run on the same physical computer in smaller applications to reduce the cost and complexity of installing smaller systems, demonstration systems or test systems. In larger systems these three functions 112, 114, 116 will typically each be hosted on separate servers. The RMS system 100 is scalable and capable of supporting in excess of one million meters. Ultimately, the number of meters supported by a single RMS 110 is a function of computer processing power and connectivity to the POS Network 130. When implementing a very large number of pre-paid meters multiple RMS systems may be linked together.

The communications server 116 acts as a gateway between the POS 130 and the business logic of the RMS architecture 110. A single business server 112 can process a high number of transactions per hour. Additional business 112 and communications 116 servers can be added as system size increases to prevent transaction processing from slowing down.

Although top-level administrative tasks can be done directly on the main server, a dedicated management PC will typically be used for this purpose. Utilities will have adequate IT infrastructure, including a LAN, already in place; in this case PCs already on an existing LAN can be used for lower level administrative access as well as to sell service credits. The RMS 100 performs the following primary functions. First, the rate structure and other charges are setup. The RMS 100 supports flat or tiered rates based on consumption and also allows charges other than service credits to be applied to a sales transaction. Examples would be public lighting fees, taxes and fuel surcharges (common in the Caribbean).

Consumer accounts also may be created. Thus, an account may be created for every consumer participating in the prepayment program. Basic data such as name, address, etc., can be imported from an existing database or created from scratch. If the consumer had a previous outstanding balance with the utility, it can be transferred to their prepayment account. Each time they purchase service credits, a predetermined portion of the total amount tendered can be applied to retiring their debt. Charges can be applied on a set schedule, or as a percentage of every transaction.

Requests for sales transactions sent through the communications server 116 to the RMS 100 include information identifying the consumer, the meter for which they want to buy service credits and the amount of money they want to spend. The RMS 100 sends this information to the database server 114, which matches it with the consumer's account information. The RMS 100 then authorizes the transaction to proceed. After allowing for any other applicable charges, the dollar (or other currency) amount of the purchase is converted into service credits and encrypted into the transfer number, which the RMS architecture 110 sends back to the POS Network 120. The RMS 100 can be programmed to restrict the total amount of service credits a consumer can buy in a given time period to prevent speculative buying.

When the transaction is complete, the consumer receives a receipt, which shows details of the transaction, and the transfer number, which the consumer can use to obtain additional utility service. A permanent record of the transaction is also created in the RMS database 114.

The RMS architecture 110 keeps a permanent record of every sales transaction. Revenue data can then be summarized for export to an accounting/financial system on a predetermined schedule or on demand. The system also includes a number of “canned” reports including an “Exception” Report that highlights consumers who are not buying electricity or buying at unusually low levels. The Exception report is a very useful tool for spotting cases of possible electricity theft.

Security is implemented in several layers. First, administrative and vending access to the system is protected by the standard Usemame/password method. Second, the POS network 120 that accesses the RMS architecture 110 via the Internet 140, always use a secure (HTTPS) connection. Dial-up access can be configured so that the system will accept incoming calls only from pre-defined telephone numbers. Security of the transfer numbers may be guaranteed by using industry-standard encryption. Transfer numbers are encrypted before being sent from the RMS architecture 110 to the POS Network 120. Each transfer number is uniquely tied to the meter for which it was created. This makes theft of a Transfer Number with the intent to use it for a different meter pointless. Also, each Transfer Number can only be used one time. If the same transfer number is received twice, it will be rejected the second time.

Within the context of existing utility infrastructure, the RMS 100 can operate in several modes. A first mode may be a prepayment only system mode of operation. In this mode of operation, a predetermined payment system is the only system used to sell electricity. Meter reading and a traditional billing system are no longer necessary because the electricity used has been paid for in advance. However, in most cases a billing program will still be used for commercial customers and other purposes such as service calls.

In a second mode of operation, the system may operate with an existing billing system. This is when both prepayment and traditional post-usage payment are offered to consumers. Consumers not on the prepayment plan still have their meters read and are then billed.

In a third mode of operation, the system may operate with an automatic meter reading system (AMRS). This is when both prepayment and traditional post-usage payment are offered to consumers, but with an AMR system reading the meters remotely via a communications path between the meter and the utility back-office. Consumers not on the prepayment plan still have their meters read by utility personnel and are then billed.

In a fourth mode of operation, the system may operate in an integrated fashion with an AMR system. In this mode of operation, when a utility has both an AMR system and the prepayment system, the transfer number can be set directly via the AMR system's communications infrastructure. In this case, other types of information/data can also be sent; such information may also be sent directly to the CIU. The RMS 100 provides daily sales data to the utility's accounting/financial system regardless of the mode of operation. In the second and third modes of operation as described above, prepayment data might be sent to a billing program with the billing program in turn sending it to an accounting/financial system. The RMS 100 also supports multiple languages simultaneously. Each user can choose the language they prefer and receipts can be printed in the customer's preferred language. This makes the system well suited for use internationally and in multi-ethnic areas while retaining a single software platform.

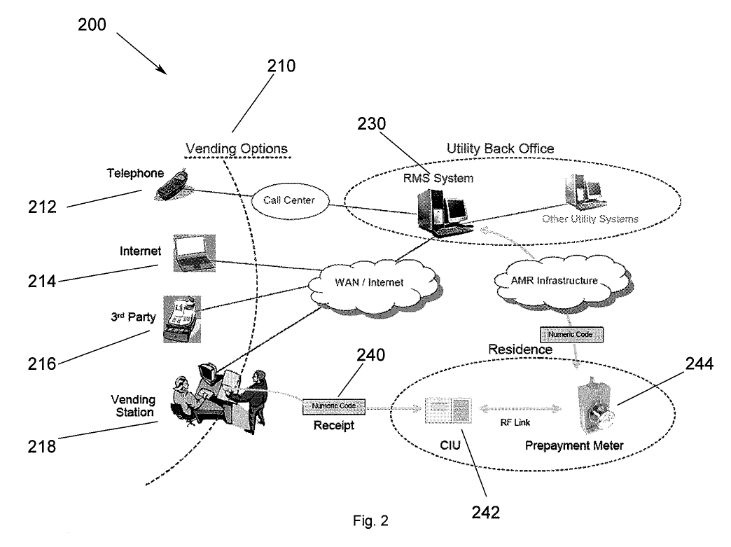

FIG. 2 illustrates a point-of-sale (POS) network 200 according to an embodiment of the present invention. A network of POS devices 200 enables sales to consumers. The point-of-sale (POS) network 200 is an IP and /or telephony based transactional network that enables the sale of electricity to consumers in multiple ways. Different types of vending options 210 are possible. For example, POS devices such as telephones 212, computers 214, 3^{rd} party devices 216 and countertop POS terminals 218 can be used within the POS network 200. The POS Network 200 is dependent upon the RMS to function but is a separate from RMS. Individual POS devices providing vending options 210 in the POS Network 200 may communicate with the RMS system 230, i.e., through the communications server 116 as described with reference to FIG. 1. However, all POS devices adhere to a predetermined communications and security protocol. In this sense, the POS Network 200 can be thought of as an extension of the RMS system 230.

The utility's payment infrastructure comprises the means by which the utility collects payment for electricity. In a traditional post-payment scenario it will be part of the utility's IT systems, but also include meter readers and a billing department. Some utilities may also have systems in place, which allow consumers to pay their bill on-line, or via telephone. The POS Network 200 can incorporate a number of different devices and services, which provide the consumer with multiple ways of purchasing electricity. The POS network sends requests for sales transactions to the RMS system 230 which authorizes them and sends back a transfer number representing the amount of electricity credits purchased.

If the utility already has a call center offering bill payment by phone, prepayment transactions can be easily added. Alternatively, a third party service provider could be used. At the conclusion of a telephone transaction, the consumer still receives a transfer number that they enter on the CIU keypad of their CIU to transfer service credits to the PPM in their meter. Internet (eCommerce) sales can also be added to an existing online bill payment system or handled by a third-party eCommerce service provider. At the conclusion of an eCommerce transaction, the consumer still receives a transfer number 240 which they enter on the keypad of the CIU 242 to transfer service credits to the PPM in their meter 244.

Cards with a fixed face value, similar to the long distance calling cards widely sold in 24-hour retail outlets, can also be supported The consumer purchases a prepaid card and then calls an 800 number. By entering their meter number and a control number on the card using the telephone keypad, they receive a transfer number. The transfer number is then permanently associated with their meter number and the card control number in the database of the RMS system 230 so that the same card cannot be used to obtain a second valid transfer number.

Table 1 below summarizes the various ways of selling electricity to consumers.

TABLE 1

| | | | Consumer | POS/RMS |
|---|---|---|---|---|
| POS Device | Hardware | Software | Interface | Connection |
| PC Based | Standard PC | Web browser | Sales person at | Broadband or |
| | | | vending | dial-up service to |
| | | | location | RMS server |
| Countertops | Ingenico, | Proprietary | Sales person at | Broadband or |
| | Veriphone or | Software | vending | dial-up service to |
| | equivalent | | location | RMS server |
| IVR | 3^{rd} party | 3^{rd} party host or | Telephone | Broadband or |
| (Interactive | payment card | utility's own | | dial-up service to |
| Voice | provider | infrastructure | | RMS server |
| Response) | | | | |
| Internet | 3^{rd} party | 3^{rd} party host or | PC/Internet | Broadband or |
| | payment card | utility's own | browser | dial-up service to |
| | provider | infrastructure | | RMS server |
| Prepaid | 3^{rd} party | Card provider | Sales person at | Broadband |
| Cards | payment card | and proprietary | vending | service |
| | provider | developed | location and | |
| | | interface to RMS | telephone | |

Vending by computer 214, countertop device 216, 218 or using cards can take place at any location where cash or credit card transactions can be handled. Utility offices, banks, credit unions and convenience stores are ideal locations.

Upon returning home, the consumer enters the transfer number 240 using the keypad on their CIU 242; the CIU 242 sends it to the PPM 244 via a wireless link between them. The PPM 244 is equipped with a microprocessor, logic and memory enabling it to decrypt transfer numbers. The PPM 244 validates the transfer number, adds the service credits to the current balance stored in memory and begins decrementing credit from the balance as service is used.

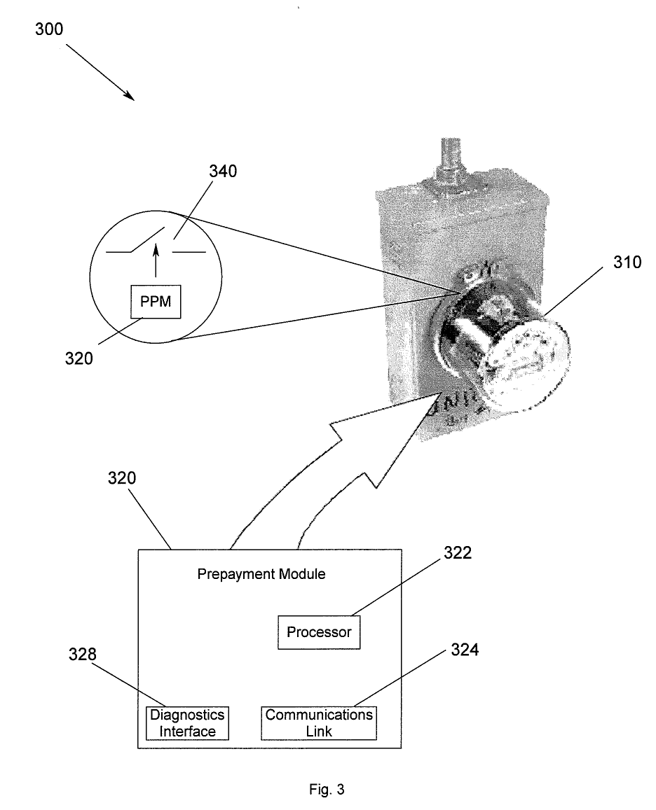

FIG. 3 illustrates a prepayment system 300 according to an embodiment of the present invention. Hardware and firmware is installed in one of a number of electrical meters 310 from suppliers to provide functionality for the prepayment module 320. For example, the prepayment module 320 may be configured to enable a meter 310 to operate in a prepayment mode within a FlexPay system.

The PPM 320 is a device that is installed inside the consumer's electrical meter 310, which enables the meter 310 to operate within a predetermined payment system. Meters 310 may be configured to provide prepayment functionality only, or to support prepayment in conjunction with an AMR system. The PPM 320 may include a communications link 324 to meter 310. The communication link may also be a serial interface. The communication link 324 also enables communication with a customer interface unit. The communication link 324 may also receive customer usage credits via the customer interface unit. A diagnostic interface 328 may be provided for allowing diagnostics to be performed.

However, the primary function of the PPM 320 is to receive and validate transfer numbers, decrypt the amount of service credits contained in the transfer number and add them to the existing credit balance. The PPM 320 then decrements credit from the available balance as electricity is used. The PPM is also responsible for disconnecting and reconnecting the supply of electricity based on remaining credits. When available service credits in PPM memory reaches zero, the PPM opens the disconnect relay, interrupting the service to the premises. When new credits are received, the PPM closes the disconnect relay, restoring service. The PPM 320 can be designed to work with many models of meters 310, which allows utilities to choose from several meter manufacturers. In the case of electricity meters 310 ,many offer enhanced features and significant advantages over older style meters, including real time usage reporting, a data communications bus and in some models a built-in disconnect relay. This is a great improvement in that availability of service in older meters is controlled by physically inserting or pulling the meter from a meter socket: a costly and potentially hazardous procedure that requires dispatch of utility personnel.

Since the PPM 320 can also include a clock/calendar chip, the meter 310 can be operated in credit mode for a predefined period to avoid disconnects during cold weather months, holidays or when the consumer might be unduly inconvenienced or endangered. Alternative methods of adding service credits are also possible, for example by sending the Transfer Number to the PPM via the communications infrastructure of and AMR system.

Some new electricity meters also have a current-limiting feature which can restrict the flow of electricity so that only a few electrical devices or appliances can be used by the consumer until full power flow is restored. The PPM 320 can activate this current limiting feature until more credits are received. When a meter has been operating in credit or current limited mode, the PPM 320 tracks the accrued deficit; when new credit is added to the PPM 320 the credit is first allocated toward retiring the accrued deficit. Alternatively, an accrued credit deficit can be converted to a “balance owed” in the RMS; each time the consumer purchases credits a percentage of the dollar (or other currency) value of the transaction can be applied to the remaining balance.

Typically, it is necessary to customize the form factor and firmware of the PPM 320 for each model of meters 310 .In the case of electricity meters, the PPM 320 is typically either socket-mounted on the metrology board of the meter 310 or connected via a connector plug. The PPM accesses the consumption data from the metrology portion of the meter and uses that data to decrement the credit balance in memory of the PPM 320.

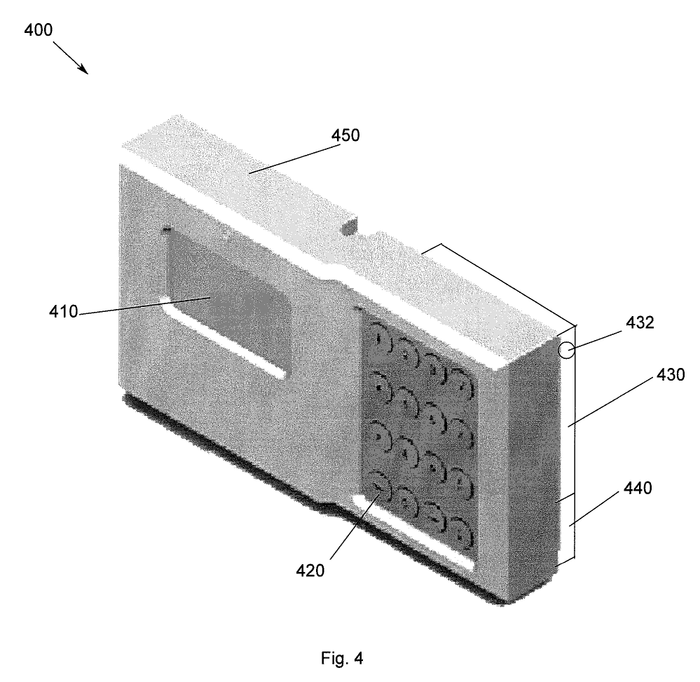

FIG. 4 illustrates a consumer interface unit (CIU) 400 according to an embodiment of the present invention. The CIU 400 includes an in-home display 410 and keypad 420 (similar in appearance to a digital thermostat), which enables consumers to manage their consumption. The display 410 provides feedback to the consumer on consumption and remaining electricity credits and the keypad 420 is used to add credit. Using the CIU 400, prepay customers input transfer numbers and monitor consumption. The CIU 400 communicates with the PPM via a two-way RF transceiver 430. The CIU is also capable of supporting a wired interface 440 for specific applications.

The CIU 400 is housed in a rugged enclosure 450 that includes a wall mounting back plate and wiring harness (not shown). A transformer or “wall pack” plugged into a local AC outlet may be used to power the CIU 400. A battery backup may also be included to power the CIU 400 if the supply of electricity to the residence is interrupted. When operating on battery power, the CIU 400 will be in a “sleep mode” until a key is pressed and will return to sleep mode after a short period if no further action is taken, thereby maximizing battery life.

The display 410 on the CIU 400 provides visual feedback on system status to the consumer. A tone generator (not shown) provides audio feedback. The keypad 420 used to enter the transfer number, is also used to acknowledge messages and otherwise respond to, and interact with, the prepayment system. One embodiment of the CIU 400 has a keypad 420 with different keys that provide the input functionality needed to enable consumption of electricity. Operation of the CIU 400 is straightforward and intuitive. The consumer may be provided an audible confirmation tone each time a key on the keypad 420 is pressed. The display 410 may provide visual indication of how quickly power is being consumed. Other indicators on the display 410 may be used to indicate whether the disconnect switch is open (service disconnected) or closed. The display 410 provides a wide range of information, such as the number of remaining credits and how long these credits are likely to last based on historical consumption patterns. The display 410 can appear in multiple languages.

Escalating visual and audible warnings may be implemented to advise the consumer that credits are running out and disconnection is imminent. If the meter is functioning in “credit” or “current limited” mode, the display will indicate it. Set-up, maintenance and troubleshooting for both the PPM and the CIU 410 are accomplished using a computer equipped with an RF interface. The CIU may accept usage credits of consumers using the RF interface 430. The RF interface 430 may also include a diagnostic interface 432 for allowing diagnostics to be performed.

It is important to note that the CIU 400 supports other advanced metering and billing applications. An example would be providing a real-time indication of the current cost of electricity when the consumer is on a time sensitive rate plan. For this reason, the CIU 400 is useful to AMR and meter companies even if prepayment may not be involved.

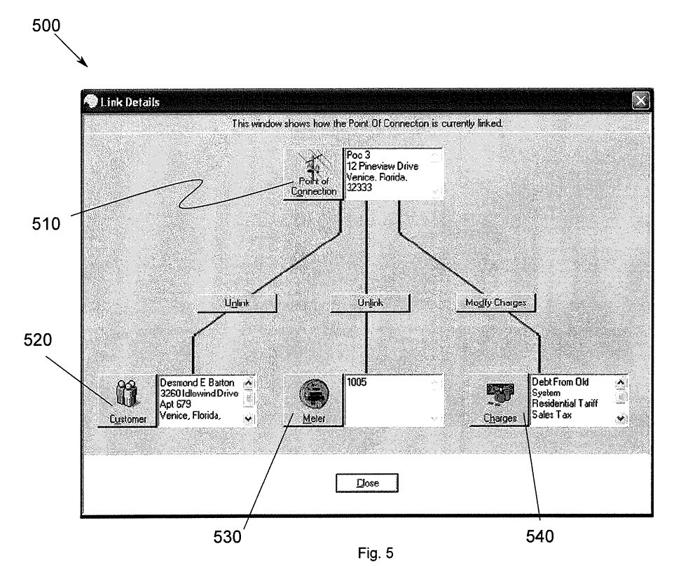

FIG. 5 is a screen shot 500 showing the functioning of the revenue management system (RMS) according to an embodiment of the present invention. Before a consumer can purchase electricity, a valid consumer record, applicable charges, and a meter number, must all be linked through the Point of Connection feature. In FIG. 5, a point of connection 510 is shown. The point of connection 510 is associated with a displayed customer 520, a distinct meter 530 and applicable charges 540.

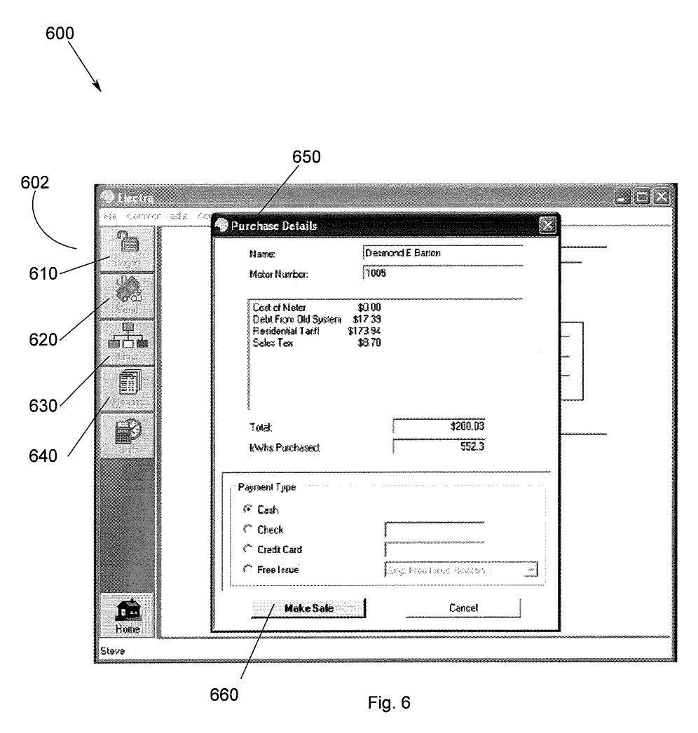

FIG. 6 is a screen shot 600 showing the vending function of the revenue management system (RMS) according to an embodiment of the present invention. Function buttons 602 are provided at the side of the screen, for example, logging off 610, vending 620, displaying links 630, printing reports 640. Other function buttons 602 are possible. The screen shot 600 also shows the details of a purchase 650. After the RMS has authorized a transaction, the sales clerk confirms details of the pending transaction with the consumer and concludes the purchase by selecting the “Make Sale” option 660.

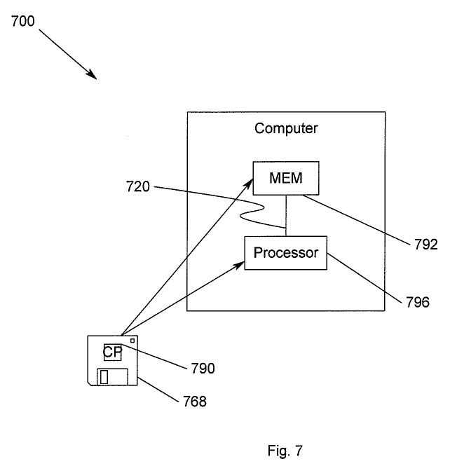

FIG. 7 illustrates a computer system 700 present invention. In FIG. 7, the computer system 700 includes memory 792 and a processor 796. A data storage device 768 provides instructions 790 to the memory 792 or processor 796 for configuring the processor 796 for performing the steps necessary to implement and/or use the present invention. Generally, the instructions or computer program 790 for providing a prepaid metering system is tangibly embodied in a computer-readable medium, e.g. one or more of the data storage devices 768. Moreover, the prepaid metering system functions are embodied in instructions 790. When the instructions 790 are read and executed by the computer system 700, the computer system 700 performs the steps necessary to implement and/or use the present invention.

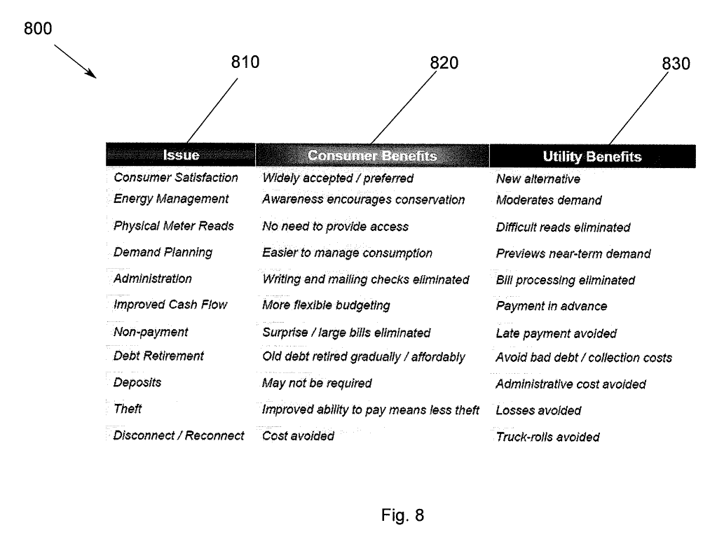

FIG. 8 is a table 800 that lists some of the advantages of a system according to embodiments of the present invention. In the table 800 of FIG. 8, the issues 810 are presented along with the associated consumer 820 and utility 830 benefits.

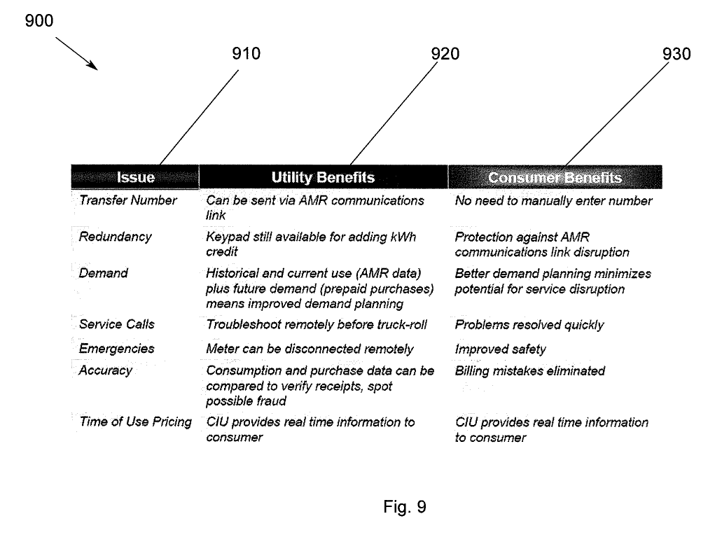

FIG. 9 is a table 900 showing further benefits of the system when used in conjunction with an AMR system or system having analogous capabilities according to an embodiment of the present invention. Again, the issues 910 are presented along with the associated consumer 920 and utility 930 benefits.

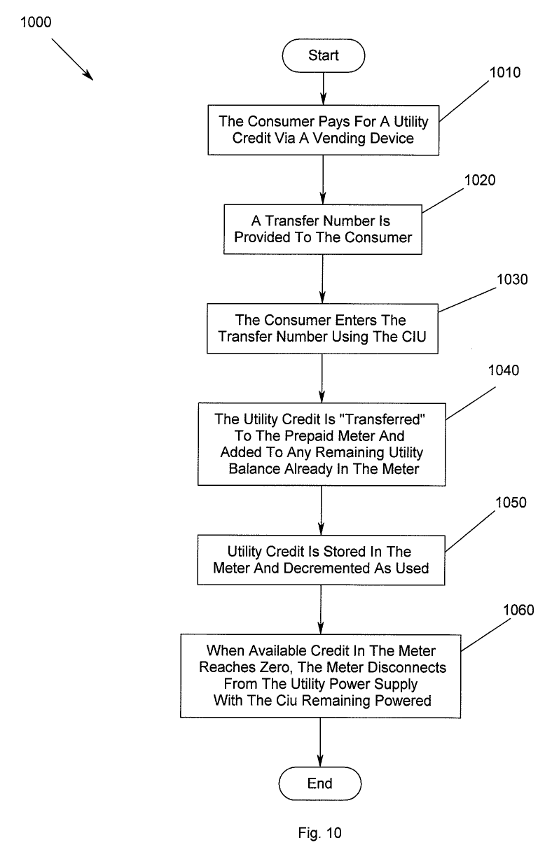

FIG. 10 is a flow chart of the method for providing prepaid metering according to one embodiment of the present invention. The consumer pays for a utility credit via a vending device 1010. A transfer number is provided to the consumer 720. The consumer enters the transfer number using the CIU 1030. The utility credit is “transferred” to the prepaid meter and added to any remaining utility balance already in the meter 1040. Utility credit is stored in the meter and decremented as used 1050. When available credit in the meter reaches zero, the meter disconnects from the utility power supply with the CIU remaining powered 1060.

The foregoing description of the embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. An electric utility meter, comprising:
a switch for controlling a connection of electric service to a customer; and
a prepayment module, coupled to the switch, for processing data regarding electricity usage by the customer, maintaining electricity usage credits for the customer and controlling the switch based on the usage credits of the customer and the data regarding electricity usage by the customer.

2. The meter of claim 1, wherein the data regarding electricity usage comprises kilowatt-hour usage measurements.

3. The meter of claim 1, wherein the prepayment module receives a measurement of electricity usage by the customer and subtracts the received measurement of electricity usage by the customer from the maintained usage credits of the customer to obtain a new customer credit balance.

4. The meter of claim 3, wherein the prepayment module causes the switch to disconnect electric service from the customer when the new customer credit balance reaches a predetermined threshold.

5. The meter of claim 1 further comprising a communications link to a meter.

6. The meter of claim 5, wherein the meter includes an automatic meter reading module for measuring customer electricity usage.

7. The meter of claim 5, wherein the communication link comprises a serial interface.

8. The meter of claim 1 further comprising a communication module for communicating with a customer interface unit.

9. The meter of claim 8, wherein the communication module comprises an RF module for providing wireless communication with the customer interface unit.

10. The meter of claim 8, wherein the communication module receives customer usage credits via the customer interface unit.

11. The meter of claim 10, wherein the prepayment module causes the switch to connect electric service to the customer when the communication module receives customer usage credits.

12. The meter of claim 1, wherein the prepayment module causes the switch to disconnect electric service to the customer when customer usage credits exceed a threshold.

13. The meter of claim 1 further comprising a diagnostic interface for allowing diagnostics to be performed.

14. The meter of claim 1, wherein the prepayment module communicates directly with an automatic meter reading system.

15. A customer interface unit, comprising:
a display for communicating information to an electric customer; and
a user interface for entering electricity usage credits for the customer and obtaining information about usage and available credits.

16. The customer interface unit of claim 15, wherein the user interface provides information about electricity usage and available credits.

17. The customer interface unit of claim 15, wherein the user interface comprises a keypad for entering information to the interface unit.

18. The customer interface unit of claim 17, wherein the information provided to the interface unit via the keypad comprises usage credits for increasing the balance of usage credits of the customer.

19. The customer interface unit of claim 15, wherein the user interface comprises an RFID interface for accepting usage credits of the customer.

20. The customer interface unit of claim 15, wherein the user interface comprises an RFID card reader.

21. The customer interface unit of claim 15, wherein the information communicated to the customer comprises at least one type of data selected from the group comprising a current cost of electricity, estimated remaining power, rate of consumption and a low power warning.

22. The customer interface unit of claim 15, wherein the RF interface comprises a diagnostic interface for allowing diagnostics to be performed.

23. The customer interface unit of claim 15 further comprising a processor for processing customer credits.

24. The customer interface unit of claim 15 further comprising backup power for allowing a customer to enter usage credits after electric service has been disconnected from the customer.

25. A revenue management system, comprising:
memory for storing data; and
a processor, coupled to the memory, the processor being configured for controlling dispensation of utility service credits, for accepting payment for utility service credits from a customer and for issuing utility service credits to the customer upon payment by the customer.

26. The revenue management system of claim 25, wherein the processor is further configured to issue utility service credits to the customer by printing a receipt having a code for entry by the customer to increase a balance of utility service credits for the customer.

27. The revenue management system of claim 25, wherein the processor is further configured to issue utility service credits of the customer to a remote accounting system, wherein the purchased utility service credits are then provided to a meter at a customer location via an automatic meter reading communications link.

28. The revenue management system of claim 25 wherein the processor is further configured to provide business server functions, database server functions, and communications server functions, wherein the business server functions controls user access and to provide a configuration interface, the database server functions for maintaining a record for each prepayment consumer and the communications server functions provides a secure communications portal.

29. The revenue management system of claim 25, wherein the memory stores data regarding the sale of credits available to other systems.

30. The revenue management system of claim 25, wherein the data regarding the sale of credits are encrypted.

31. The revenue management system of claim 25, wherein the utility service credits are uniquely coded for a meter of the customer.

32. The revenue management system of claim 25, wherein the processor is further configured to support multiple languages simultaneously.

33. The revenue management system of claim 25, wherein the processor is further configured to issue credits based upon differing tariff rates.

34. The revenue management system of claim 25, wherein the processor is further configured to provide an automated telephone response system.

35. The revenue management system of claim 25, wherein the processor is further configured to provide an Internet based customer interface.

36. The revenue management system of claim 25, wherein the processor is further configured to allow a continued flow of electricity to the customer in a credit mode.

37. The revenue management system of claim 36, wherein the processor is further configured to move in and out of credit mode based on predetermined parameters.

38. The revenue management system of claim 36, wherein the processor is further configured to allocate purchased customer credits first to accumulated usage while in credit mode and then to advance purchases.

39. The revenue management system of claim 25, wherein the processor is further configured to provide information regarding purchased credits to a customer metering system.

40. The revenue management system of claim 25, wherein the processor is further configured to provide information regarding purchased credits to a customer metering system via an automatic meter reading link.

41. A method for providing prepaid utility metering, comprising:
paying by a consumer for a utility credit via a vending device;
providing a transfer number to the consumer in response to receipt of the payment;
entering the transfer number using the CIU;
transferring the utility credit to the prepaid meter and adding to any remaining utility balance already in the meter;
storing utility credit in the meter and decrementing the utility credit as used; and
disconnecting the meter from the utility power supply when available credit in the meter reaches zero while maintaining power to the CIU.

42. A program storage device, comprising:
program instructions executable by a processing device to perform operations for providing a user mode device interface for providing request trace data by:
paying by a consumer for a utility credit via a vending device;
providing a transfer number to the consumer in response to receipt of the payment;
entering the transfer number using the CIU;
transferring the utility credit to the prepaid meter and adding to any remaining utility balance already in the meter;
storing utility credit in the meter and decrementing the utility credit as used; and
disconnecting the meter from the utility power supply when available credit in the meter reaches zero while maintaining power to the CIU.
